(19) United States
(12) Patent Application Publication
(10) Pub. No.: US 2009/0014896 A1
(43) Pub. Date: Jan. 15, 2009

(54) Flip-chip package structure, and the substrate and the chip thereof

(75) Inventor: Shih-Ping Hsu, Hsin-feng (TW)

Correspondence Address: BACON & THOMAS, PLLC, 625 SLATERS LANE, FOURTH FLOOR, ALEXANDRIA, VA, 22314-1176, US

(73) Assignee: Phoenix Precision Technology Corporation, Hsinchu (TW)

(21) Appl. No.: 12/216,850

(22) Filed: Jul. 11, 2008

(30) Foreign Application Priority Data
Jul. 13, 2007 (TW) 096125664

(51) Int. Cl. H01L 23/52

(52) U.S. Cl. 257/778; 257/E23.141

(57) ABSTRACT

A flip-chip package structure is disclosed, which comprises: a packaging substrate having an upper surface and a plurality of conductive pads formed on the upper surface; a semiconductor chip having an active surface and a plurality of electrode pads formed on the active surface; and a plurality of first solder bumps; wherein each first solder bump connects to an electrode pad and a conductive pad, and each first solder bump contains a solid grain.

### BACKGROUND OF THE INVENTION

1. Field of the Invention

The present invention relates to a flip-chip package structure and, more particularly, to a flip-chip package structure with fine line width and fine line pitch.

2. Description of Related Art

As performance of semiconductor processes advances, semiconductor chips formed thereby have more and stronger functions and tend towards complexity. At the same time, amounts of transmission data of semiconductors increase more and more. Therefore, quantities of I/O (inputs/outputs) contact pads of semiconductor chips have to increase in accordance with the above-mentioned.

As chip techniques have developed towards high work frequency and larger amounts of I/O contact pads, conventional wire bonding has failed to satisfy demands of conductivity. Compared with conventional wire bonding, a flip-chip package process is a technique that a chip faces downward to conduct a packaging substrate by means of solder bumps. Besides, I/O contact pads can be distributed on the whole surface of the chip so that advantages can be achieved as follows: large increase in amounts of signal input/output contact pads of the chip, shortening of transmission paths of signals, decrease in interference of noises, promotion of heat dissipating, and shrinking package volume. Hence, the flip-chip package process has already become a main trend in the industry.

As shown in FIG. 1, a conventional flip-chip packaging substrate is shown. The surface of the packaging substrate 11 has a plurality of conductive pads 12 and a patterned solder mask 13, in which the solder mask 13 is patterned so as to expose the conductive pads 12. At the same time, a plurality of solder bumps 14 is formed on the surface of the conductive pads 12 by electroplating or printing method, wherein the solder bumps 14 can be made of a lead-tin alloy or a tin metal. Furthermore, a plurality of electrode pads 21 is located on the active surface of the chip 20, a patterned passivation layer 23 is provided on the active surface, wherein the passivation layer 23 is patterned so as to expose the electrode pads 21. A plurality of solder bumps 25 is provided on the surface of the electrode pads 21 by electroplating and reflow soldering. Herein, the solder bumps 14,25 can have a solder joint and electrically connect the chip 20 and the packaging substrate 11.

An underfill material then fills the interval between the chip 20 and the packaging substrate 11 after the connection of the chip 20 and the packaging substrate 11 so as to fix the chip and enhance reliability. By filling the underfill material in the interval between the chip and the packaging substrate, following with curing the underfill material, the chip can be fixed and the reliability of the package structure can be enhanced.

Although such structure and the method of providing the same can be used for electrical conduction, it has restrictions when the character of fine line width and fine line pitch is required. In reference to FIG. 1, with the requirement of multifunction for the contemporary semiconductors, the distribution density of the electrode pads on the active surface of the chip is increased such that the diameter of the solder bump 25 has to become smaller. Accordingly, the distribution density of the corresponding conductive pad is raised due to the small diameter of the solder bump 25, and further results in a low interval height between the chip 20 and the packaging substrate 11. Therefore, in order to produce a chip with the design of high circuit density of electrode pads, it is an essential need for the development of packaging substrates to have fine line width and fine line pitch.

In addition, miniaturizing the volume of the solder bumps 25 is a way to satisfy the demand of fine line width and fine line pitch of the electrode pads 21 and the conductive pads 12. However, when the size of the solder bumps 25 is smaller, the height of the interval between the packaging substrate and the chip is decreased, which further results in unusual filling of the underfill material and the occurrence of voids in the underfill material when it fills in the interval between the packaging substrate and the chip. Also, serious problems such as cracking of the packaging substrate will possibly occur and result in deterioration of the reliability. Consequently, the conventional method of forming the bump is not suitable for the producing of the IC packaging substrate having fine line width and fine line pitch. Hence, a flip-chip package structure favoring fine line width and fine line pitch and without the shortcomings illustrated above is urgently required.

### SUMMARY OF THE INVENTION

An object of the present invention is to provide a flip-chip package structure, which can provide a semiconductor chip package with characteristics of fine line width and fine line pitch.

Another object of the present invention is to provide a flip-chip package structure, which is able to improve the thermo stress of the flip-chip package structure, improve the quality of underfill material filling, and enhance the reliability of the flip-chip package structure.

Still another object of the present invention is to provide a flip-chip packaging substrate, which can be used in the above mentioned flip-chip package structure.

Yet another object of the present invention is to provide a semiconductor chip for a flip-chip, which can be used in the above mentioned flip-chip package structure.

To achieve the above object, the flip-chip package structure of the present invention comprises: a packaging substrate having an upper surface and a plurality of conductive pads formed on the upper surface of the substrate; a semiconductor chip having an active surface and a plurality of electrode pads formed on the active surface; and a plurality of first solder bumps, wherein each first solder bump connects to an electrode pad and a conductive pad, and each first solder bump comprises a solid grain.

Another flip-chip package structure of the present invention comprises: a packaging substrate having an upper surface and a plurality of conductive pads locating on the upper surface of the substrate; a plurality of third solder bumps connecting to the conductive pads; a semiconductor chip having an active surface and a plurality of electrode pads formed on the active surface; a plurality of second solder bumps connecting to the electrode pads; and a plurality of solid grains, wherein the solid grains are correspondingly connecting to the second solder bumps and the third solder bumps.

The flip-chip package structure of the present invention may preferably further comprise an underfill material filled between the packaging substrate and the semiconductor chip.

According to the flip-chip package structure of the present invention, preferably, the semiconductor chip may further comprise a passivation layer covering the active surface, and the passivation layer has a plurality of openings to expose the electrode pads.

According to the flip-chip package structure of the present invention, preferably, the packaging substrate may further comprise a solder mask formed on the upper surface, and the solder mask has a plurality of openings to expose the conductive pads.

According to the flip-chip package structure of the present invention, preferably, the diameter of the solid grain may be smaller than the width of the first solder bump.

According to the flip-chip package structure of the present invention, preferably, the diameter of the solid grain may be larger than the width of the second solder bump and the third solder bump.

According to the flip-chip package structure of the present invention, the shape of the solid grain is not limited but preferably the solid grain is a spherical shaped grain, or an ellipsoid shaped grain.

According to the flip-chip package structure of the present invention, the solid grain is preferably a metal grain, or a grain having a hard resin as a core and coated with metal.

According to the flip-chip package structure of the present invention, the conductive pads are preferably copper pads.

According to the flip-chip package structure of the present invention, the electrode pads are preferably aluminum pads, or copper pads.

According to the flip-chip package structure of the present invention, the third solder bumps and the second solder bumps are preferably made of one selected from the group consisting of: lead, tin, silver, and copper.

The flip-chip packaging substrate of the present invention comprises: a packaging substrate having an upper surface and a plurality of conductive pads formed on the upper surface of the substrate; a solder mask forming on the surface of the substrate, and the solder mask has a plurality of openings to expose the conductive pads; a plurality of third solder bumps connecting to the conductive pads; and a plurality of solid grains, wherein the solid grains are located on the third solder bumps.

According to the flip-chip packaging substrate of the present invention, the shape of the solid grain is not limited but preferably the solid grain is a spherical shaped grain, or an ellipsoid shaped grain.

According to the flip-chip packaging substrate of the present invention, the solid grain is preferably a metal grain, or a grain having a hard resin as a core and coated with metal.

According to the flip-chip packaging substrate of the present invention, the conductive pads are preferably copper pads.

According to the flip-chip packaging substrate of the present invention, the third solder bumps are preferably made of one selected from the group consisting of: lead, tin, silver, and copper.

The package chip for flip-chip of the present invention comprises: a semiconductor chip having an active surface and a plurality of electrode pads locating on the active surface; a passivation layer covering on the active surface, and the passivation layer has a plurality of openings to expose the electrode pads; a plurality of second solder bumps connecting to the electrode pads; and a plurality of solid grains, wherein the solid grains are locating on the second solders.

According to the package chip of the present invention, the shape of the solid grain is not limited but preferably the solid grain is a spherical shaped grain, or an ellipsoid shaped grain.

According to the package chip of the present invention, the solid grain is preferably a metal grain, or a grain having a hard resin as a core and coated with metal.

According to the package chip of the present invention, the electrode pads are preferably aluminum pads, or copper pads.

According to the package chip of the present invention, the second solder bumps are preferably made of one selected from the group consisting of: lead, tin, silver, and copper.

### BRIEF DESCRIPTION OF THE DRAWINGS

FIG. 1 is a schematic view of a conventional flip-chip package structure;

FIGS. 2 to 5 are schematic views of the flip-chip package structure of Example 1 of the present invention; and

FIGS. 6 to 8 are schematic views of the flip-chip package structure of Example 2 of the present invention.

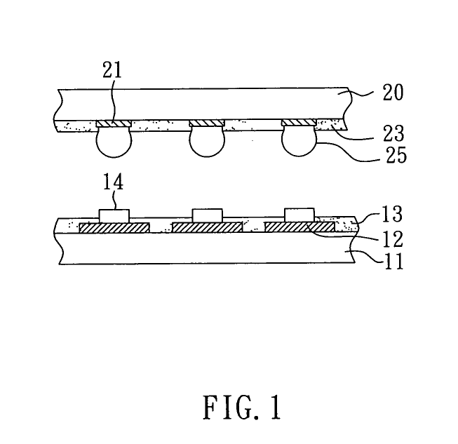

### DETAILED DESCRIPTION OF THE PREFERRED EMBODIMENT

Because of the specific embodiments illustrating the practice of the present invention, a person having ordinary skill in the art can easily understand other advantages and efficiency of the present invention through the content disclosed therein. The present invention can also be practiced or applied by other variant embodiments. Many other possible modifications and variations of any detail in the present specification based on different outlooks and applications can be made without departing from the spirit of the invention.

The drawings of the embodiments in the present invention are all simplified charts or views, and only reveal elements relative to the present invention. The elements revealed in the drawings are not necessarily aspects of the practice, and quantity and shape thereof are optionally designed. Further, the design aspect of the elements can be more complex.

### Example 1

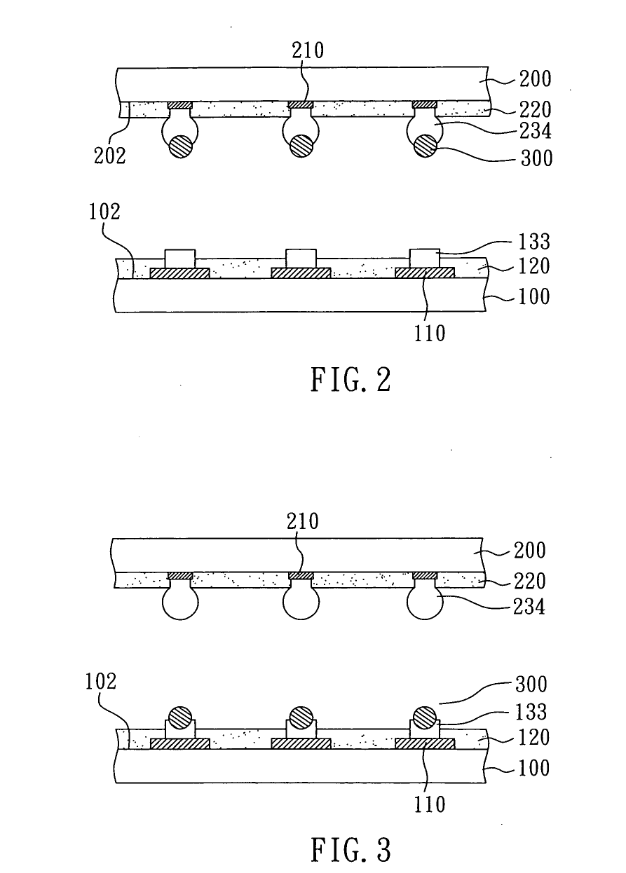

Referring to FIG. 2, the flip-chip package structure of the present Example 1 comprises: a packaging substrate 100 and a semiconductor chip 200. A plurality of conductive pads 110 and a solder mask 120 are formed on the upper surface 102 of the substrate 100, a plurality of openings is formed in the solder mask 120 to expose the conductive pads 110, and a plurality of third solder bumps 133 is provided on the conductive pads 110 correspondingly. A plurality of electrode pads 210 and a passivation layer 220 covering the active surface 202 of the semiconductor chip 200, in which the passivation layer 220 has a plurality of openings to expose the electrode pads 210. Second solder bumps 234 are located on the electrode pads 210 correspondingly. Further, solid grains 300 are located on the second solder bumps 234, wherein the diameter of the solid grain 300 is smaller than the width of the second solder bump 234.

In the present example, the solid grain 300 can be a hard metal grain, or a grain having a hard resin as a core and coated with metal. The conductive pad 110 locating on the packaging substrate 100 can be a copper pad, and the third solder bumps 133 can be one selected from the group consisting of: lead, tin, silver, and copper. The electrode pads 210 locating on the semiconductor chip 200 can be aluminum pads or copper pads, and the second solder bumps 234 can be one selected from the group consisting of: lead, tin, silver, and copper.

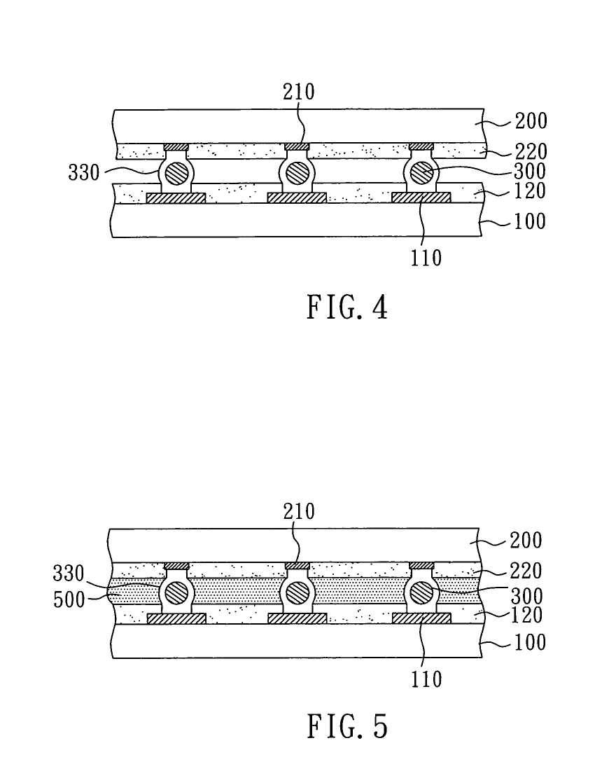

The electrically connections between the electrode pads 210 of the semiconductor chip 200 and the conductive pads 110 of the packaging substrate 100 are performed by contacting the solid grains 300 locating on the second solder bumps 234 and the third solder bumps 133 locating on the packaging substrate 100 continued with reflow soldering at about 230° C. During the process of reflow soldering, the second solder bumps 234 of the semiconductor chip 200 and the third solder bumps 133 of the packaging substrate 100 are melted, blended with each other, and connected. The solid grain 300 is surrounded by the melted second solder bump 234 and the third solder bump 133 during the melting and connecting process as shown in FIG. 4. After finishing the reflow soldering process, the second solder bumps 234 and the third solder bumps 133 fuse together and form first solder bumps 330, wherein each of the first solder bumps 330 has a solid grain 300 inside.

After the process of reflow soldering, in the present example, an underfill material 500 fills between the semiconductor chip 200 and the substrate 100, as shown in FIG. 5, thus a flip-chip package structure is completed.

In the traditional packaging process of the substrate and the semiconductor chip having fine line width and fine line pitch, the volume of the second solder bumps (locating on the semiconductor chip) is usually required to be reduced in order to fit the requirement of high circuit density with fine line width and fine line pitch, which results in the decreasing height between the semiconductor chip and the packaging substrate and further causing unusual filling of underfill material or incurring voids.

Because a solid grain 300 is located between the semiconductor chip 200 and the packaging substrate 100, in the present example, the height of the interval between the semiconductor chip 200 and the packaging substrate 100 can be increased during the reflow soldering process so as to ensure the filling of the underfill material. Thereby, the difficulties occurring when the character of fine line width and fine line pitch is required can be improved, and thus can meet the requirement of fine line width and fine line pitch. Further, the height of the interval between the semiconductor chip 200 and the packaging substrate 100 is tunable by adjusting the diameter of the solid grains 300, which makes the selection of the materials and the design have more choices.

On the other hand, in the present example, changing the solid grain 300 raises the height of the interval between the semiconductor chip 200 and the packaging substrate 100 and increases the thickness of the underfill material 500. Therefore, when the working temperature of the semiconductor chip 200 is increased, the underfill material 500 is able to ease the thermo stress between the semiconductor chip 200 and the packaging substrate 100, thus the reliability of the product is enhanced.

Alternatively, the solid grain 300 in the above mentioned flip-chip package structure could also locate on the third solder bumps 133 of the packaging substrate 100, as shown in FIG. 3. A plurality of conductive pads 110 and a solder mask 120 are forming on the upper surface 102 of the packaging substrate 100, a plurality of openings is formed in the solder mask 120 to expose the conductive pads 110, and a plurality of third solder bumps 133 is provided on the conductive pads 110 correspondingly. Herein, the solid grains 300 locate on the third solder bumps 133 of the packaging substrate 100. After the reflow soldering process, in the present example, the flip-chip package structure can be formed and shown as FIG. 4.

### Example 2

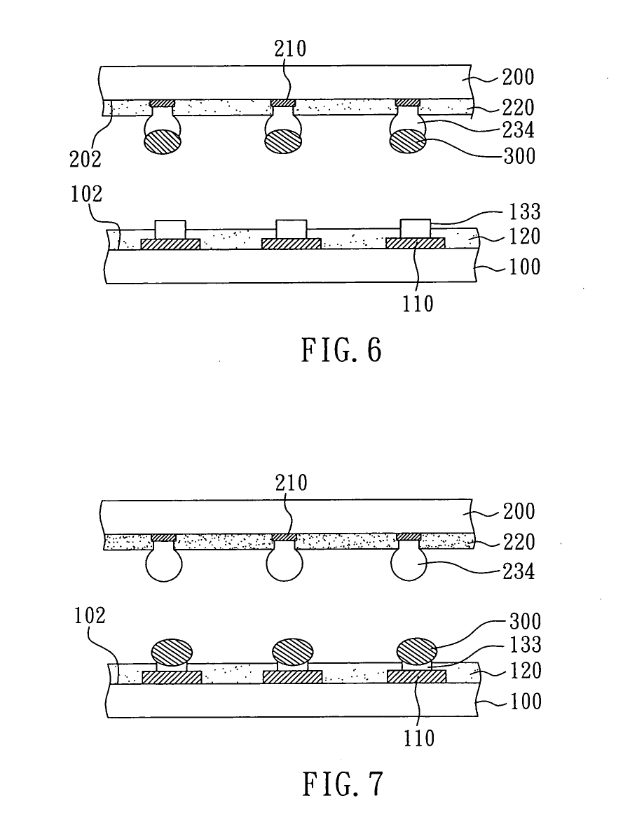

Referring to FIG. 6, the flip-chip package structure according to the present example includes a packaging substrate 100 and a semiconductor chip 200. A plurality of conductive pads and 110 and a solder mask 120 are formed on the upper surface 102 of the packaging substrate 100, a plurality of openings is formed in the solder mask 120 to expose the conductive pads 110, and a plurality of third solder bumps 133 is provided on the conductive pads 110 correspondingly. A plurality of electrode pads 210 and a passivation layer 220 covering the active surface 202 of the semiconductor chip 200, in which the passivation layer 220 has a plurality of openings to expose the electrode pads 210. Second solder bumps 234 are located on the electrode pads 210 correspondingly. Further, solid grains 300 are located on the second solder bumps 234, wherein the diameter of the solid grain 300 is larger than the width of the second solder bump 234.

In the present example, the solid grain 300 is a hard metal ellipsoid shaped grain, and the diameter of the solid grain 300 is larger than the width of the second solder bump 234 as shown in FIG. 5. The conductive pad 110 locating on the packaging substrate 100 can be a copper pad, and the third solder bumps 133 can be one selected from the group consisting of: lead, tin, silver, and copper. The electrode pads 210 locating on the semiconductor chip 200 can be aluminum pads or copper pads, and the second solders 234 can be one selected from the group consisting of: lead, tin, silver, and copper.

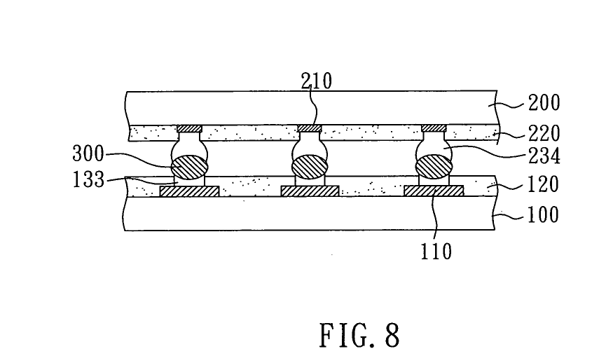

Referring to FIG. 8, the electrical connections between the electrode pads 210 of the semiconductor chip 200 and the conductive pads 110 of the packaging substrate 100 are performed by contacting the solid grains 300 locating on the second solder bumps 234 and the third solder bumps 133 locating on the packaging substrate 100 is continued with reflow soldering at about 230° C. During the process of reflow soldering, as shown in FIG. 6, the second solder bumps 234 and the third solder bumps 133 are melted, so that the second solder bumps 234 and the third solder bumps 133 connect to the solid grain 300 respectively. In the present invention, the diameter of the solid grain 300 is larger than the width of the third solder bump 133 and the second solder bump 234. After finishing the reflow soldering process, the third solder bumps 133, as shown in FIG. 6, will tightly adhere to the solid grain 300, and so will the second solder bump 234 tightly adhere to the solid grain 300, as shown in FIG. 8. Therefore, the each third solder bump 133 connects to the respective solid grain 300 and the conductive pad 110, the each second solder bump 234 connects to the respective solid grain 300 and the electrode pad 210 of the semiconductor chip 200, as shown in FIG. 8. After finishing the reflow soldering process, the second solder bumps 234 and the third solder bumps 133 fuse together and form first solder bumps 330, wherein each of the first solder bumps 330 has a solid grain 300 inside.

After finishing the above mentioned reflow soldering process, an underfill material 500 can fill between the semiconductor chip 200 and the packaging substrate 100, as described in the Example 1 (reference with FIG. 5), thus a flip-chip package structure is completed.

Alternatively, the solid grain 300 in the present example can also locate on the third solder bumps 133 of the packaging substrate 100, as shown in FIG. 7. A plurality of conductive pads 110 and a solder mask 120 are forming on the upper surface 102 of the packaging substrate 100, a plurality of openings is formed in the solder mask 120 to expose the conductive pads 110, and a plurality of third solder bumps 133 is provided on the conductive pads 110 correspondingly. Herein, the solid grain 300 locates on the third solder bump 133 of the packaging substrate 100. After the reflow soldering process, in the present example, the flip-chip package structure can be formed and shown as FIG. 8.

Such that the requirement of fine line width and fine line pitch for the package structure (of the semiconductor chip and the packaging substrate) can be achieved, and the reduction in height of the interval between the semiconductor chip and the packaging substrate is avoided, thus the present process is capable of preventing unusual filling of underfill material or preventing voids formed in the underfill material. Consequently, the package structure with fine line width and fine line pitch is easily provided.

Although the present invention has been explained in relation to its preferred embodiment, it is to be understood that many other possible modifications and variations can be made without departing from the scope of the invention as hereinafter claimed.

What is claimed is:

1. A flip-chip package structure, which comprises:
a packaging substrate having an upper surface and a plurality of conductive pads formed on the upper surface of the substrate;
a semiconductor chip having an active surface and a plurality of electrode pads formed on the active surface; and
a plurality of first solder bumps, wherein each first solder bump connects to an electrode pad and a conductive pad, and each first solder bump comprises a solid grain.

2. The flip-chip package structure as claimed in claim 1, further comprising an underfill material filled between the packaging substrate and the semiconductor chip.

3. The flip-chip package structure as claimed in claim 1, wherein the semiconductor chip further comprises a passivation layer covering the active surface, and the passivation layer has a plurality of openings to expose the electrode pads.

4. The flip-chip package structure as claimed in claim 1, wherein the packaging substrate further comprises a solder mask forming on the upper surface, and the solder mask has a plurality of openings to expose the conductive pads.

5. The flip-chip package structure as claimed in claim 1, wherein the diameter of the solid grain is smaller than the width of the first solder bump.

6. The flip-chip package structure as claimed in claim 1, wherein the solid grain is a metal grain, or a grain having a hard resin as a core and coated with metal.

7. The flip-chip package structure as claimed in claim 1, wherein the conductive pads are copper pads.

8. The flip-chip package structure as claimed in claim 1, wherein the electrode pads are aluminum pads, or copper pads.

9. The flip-chip package structure as claimed in claim 1, wherein the first solder bumps are made of one selected from the group consisting of: lead, tin, silver, and copper.

10. A flip-chip package structure, which comprises:
a packaging substrate having an upper surface and a plurality of conductive pads locating on the upper surface of the substrate;
a plurality of third solder bumps connecting to the conductive pads;
a semiconductor chip having an active surface and a plurality of electrode pads formed on the active surface;
a plurality of second solder bumps connecting to the electrode pads; and
a plurality of solid grains, wherein the solid grains are correspondingly connected to the second solder bumps and the third solder bumps.

11. The flip-chip package structure as claimed in claim 10, wherein the diameter of the solid grain is larger than the width of the second solder bump and the third solder bump.

12. The flip-chip package structure as claimed in claim 10, further comprising an underfill material filled between the packaging substrate and the semiconductor chip.

13. The flip-chip package structure as claimed in claim 10, wherein the semiconductor chip further comprises a passivation layer covering the active surface, and the passivation layer has a plurality of openings to expose the electrode pads.

14. The flip-chip package structure as claimed in claim 10, wherein the packaging substrate further comprises a solder mask forming on the surface of the substrate, and the solder mask has a plurality of openings to expose the conductive pads.

15. The flip-chip package structure as claimed in claim 10, wherein the conductive pads are copper pads.

16. The flip-chip package structure as claimed in claim 10, wherein the electrode pads are aluminum pads, or copper pads.

17. The flip-chip package structure as claimed in claim 10, wherein the third solder bumps or the second solder bumps are made of one selected from the group consisting of: lead, tin, silver, and copper.

18. A flip-chip packaging substrate, which comprises:
a packaging substrate having an upper surface and a plurality of conductive pads formed on the upper surface of the substrate;
a solder mask forming on the surface of the substrate, and the solder mask has a plurality of openings to expose the conductive pads;
a plurality of third solder bumps connecting to the conductive pads; and
a plurality of solid grains, wherein the solid grains are located on the third solder bumps.

19. The flip-chip packaging substrate as claimed in claim 18, wherein the solid grain is a metal grain, or a grain having a hard resin as a core and coated with metal.

20. The flip-chip packaging substrate as claimed in claim 18, wherein the conductive pads are copper pads.

21. The flip-chip packaging substrate as claimed in claim 18, wherein the third solder bumps are made of one selected from the group consisting of: lead, tin, silver, and copper.

22. A package chip for flip-chip, comprising:
a semiconductor chip having an active surface and a plurality of electrode pads locating on the active surface;
a passivation layer covering on the active surface, and the passivation layer has a plurality of openings to expose the electrode pads;
a plurality of second solder bumps connecting to the electrode pads; and
a plurality of solid grains, wherein the solid grains are located on the second solder bumps.

23. The package chip as claimed in claim 22, wherein the solid grain is a metal grain, or a grain having a hard resin as a core and coated with metal.

24. The package chip as claimed in claim 22, wherein the electrode pads are aluminum pads, or copper pads.

25. The package chip as claimed in claim 22, wherein the second solder bumps are made of one selected from the group consisting of: lead, tin, silver, and copper.
